(19) United States
(12) Patent Application Publication
(10) Pub. No.: US 2026/0204870 A1
(43) Pub. Date: Jul. 16, 2026

(54) METHOD FOR MANUFACTURING SEMICONDUCTOR OPTICAL DEVICE, METHOD FOR MANUFACTURING CAN-TYPE OPTICAL MODULE, AND SEMICONDUCTOR OPTICAL DEVICE

(71) Applicant: Mitsubishi Electric Corporation, Tokyo (JP)

(72) Inventors: Yusuke AZUMA, Tokyo (JP); Akihiro MATSUSUE, Tokyo (JP)

(73) Assignee: Mitsubishi Electric Corporation, Tokyo (JP)

(21) Appl. No.: 19/384,695

(22) Filed: Nov. 10, 2025

(30) Foreign Application Priority Data
Jan. 15, 2025 (JP) 2025-005117

(51) Int. Cl. H01S 5/10; H01S 5/02212

(52) U.S. Cl. CPC H01S 5/101; H01S 5/02212

(57) ABSTRACT

A method for manufacturing a semiconductor optical device includes: forming two semiconductor optical devices, each of which includes a waveguide including an oblique waveguide portion extending obliquely with respect to a front-end surface, in a semiconductor substrate so that the front-end surfaces of the two semiconductor optical devices face each other; forming a light emitting point recognition pattern, which extends from one of the two semiconductor optical devices to the other through a border region of the two semiconductor optical devices, on a surface of the semiconductor substrate; and cleaving the semiconductor substrate within the border region to separate the two semiconductor optical devices.

### BACKGROUND OF THE INVENTION

### Field

The present disclosure relates to a method for manufacturing a semiconductor optical device, a method for manufacturing a CAN-type optical module, and a semiconductor optical device.

### Background

A CAN-type optical module in which a semiconductor optical device is covered with a lens-equipped cap is used (for example, see Patent Literature 1). Since light collected through a lens needs to be coupled to an optical fiber at a proper position, it is necessary to perform precise alignment of positions of the lens-equipped cap and a light emitting point of the semiconductor optical device in capping. In view of this, a groove is formed in the vicinity of the light emitting point of a front-end surface of the semiconductor optical device, and the groove is subjected to image recognition to align the positions of the lens-equipped cap and the light emitting point of the semiconductor optical device in capping.

Chips in each of which a laser and another function are integrated, e.g., EML chips in each of which an EA modulator and a laser are integrated, are generally formed so that front-end surfaces of two chips face each other in a wafer plane. The two chips are separated from each other by cleavage. In the case where a waveguide and a groove for light emitting point recognition are formed perpendicular to the front-end surface, the shapes of the waveguide and the groove are not changed within a variation range of a cleavage position; thus, even when the cleavage position varies, a positional relation between the groove and the light emitting point which is obtained from observation of a front-end surface is the same.

### CITATION LIST

### Patent Literature

Patent Literature 1: JP 7036286 B2

### SUMMARY

### Technical Problem

In a laser chip for which high output is desired, such as an SOA integrated EML, a large amount of light is reflected and returned from a front-end surface, which adversely affects characteristics. In view of this, a waveguide is formed obliquely with respect to the front-end surface to reduce light which is reflected and returned from the front-end surface to a laser portion. In this case, the shapes or positions of the waveguide and the groove are changed within the variation range of the cleavage position. Hence, when the cleavage position is deviated, a chip including no groove in a front-end surface is provided, which causes a problem of lowering production efficiency.

The present disclosure is made to solve a problem such as that described above, and an object thereof is to obtain a method for manufacturing a semiconductor optical device which can improve production efficiency, a method for manufacturing a CAN-type optical module, and a semiconductor optical device.

### Solution to Problem

A method for manufacturing a semiconductor optical device according to the present disclosure includes: forming two semiconductor optical devices, each of which includes a waveguide including an oblique waveguide portion extending obliquely with respect to a front-end surface, in a semiconductor substrate so that the front-end surfaces of the two semiconductor optical devices face each other; forming a light emitting point recognition pattern, which extends from one of the two semiconductor optical devices to the other through a border region of the two semiconductor optical devices, on a surface of the semiconductor substrate; and cleaving the semiconductor substrate within the border region to separate the two semiconductor optical devices.

### Advantageous Effects of Invention

In the present disclosure, the light emitting point recognition pattern is formed to extend from one of the two semiconductor optical devices to the other thereof through the border region where cleavage is to be performed. Thus, even when the cleavage position varies in the border region, the cleavage occurs across the light emitting point recognition pattern without fail; therefore, a semiconductor optical device including no light emitting point recognition pattern in the front-end surface is not provided. Hence, misrecognition of the light emitting point can be prevented, and thus, production efficiency can be improved.

### BRIEF DESCRIPTION OF DRAWINGS

FIG. 1 is a perspective view illustrating a CAN-type optical module according to a first embodiment.

FIG. 2 is a plan view illustrating a method for manufacturing the semiconductor optical device according to the first embodiment.

FIG. 3 is an enlarged plan view of the border region of the two semiconductor optical devices of FIG. 2.

FIG. 4 illustrates the front-end surface of the semiconductor optical device according to the first embodiment.

FIG. 5 illustrates a method for manufacturing the CAN-type optical module according to the first embodiment.

FIG. 6 is a plan view illustrating a method for manufacturing a semiconductor optical device according to the first comparison example.

FIG. 7 is a plan view illustrating a method for manufacturing a semiconductor optical device according to the second comparison example.

FIG. 8 is an enlarged plan view of the border region in a method for manufacturing a semiconductor optical device according to a second embodiment.

FIG. 9 is an enlarged plan view of the border region in a method for manufacturing a semiconductor optical device according to a third embodiment.

FIG. 10 illustrates the front-end surface of the semiconductor optical device according to the third embodiment.

FIG. 11 is an enlarged plan view of the border region in a method for manufacturing a semiconductor optical device according to a fourth embodiment.

FIG. 12 illustrates the front-end surface of the semiconductor optical device according to the fourth embodiment.

FIG. 13 is an enlarged plan view of the border region in a method for manufacturing a semiconductor optical device according to a fifth embodiment.

FIG. 14 illustrates the front-end surface of the semiconductor optical device according to the fifth embodiment.

FIG. 15 illustrates the front-end surface of a semiconductor optical device according to a sixth embodiment.

FIG. 16 illustrates a modification example of the front-end surface of the semiconductor optical device according to the sixth embodiment.

FIG. 17 is an enlarged plan view of the border region in a method for manufacturing a semiconductor optical device according to a seventh embodiment.

FIG. 18 illustrates the front-end surface of the semiconductor optical device according to the seventh embodiment.

FIG. 19 is an enlarged plan view of the border region in a method for manufacturing a semiconductor optical device according to an eighth embodiment.

FIG. 20 illustrates the front-end surface of the semiconductor optical device according to the eighth embodiment.

FIG. 21 is an enlarged plan view of the border region in a method for manufacturing a semiconductor optical device according to a ninth embodiment.

FIG. 22 illustrates the front-end surface of the semiconductor optical device according to the ninth embodiment.

### DESCRIPTION OF EMBODIMENTS

A method for manufacturing a semiconductor optical device, a method for manufacturing a CAN-type optical module, and a semiconductor optical device according to the embodiments of the present disclosure will be described with reference to the drawings. The same components will be denoted by the same symbols, and the repeated description thereof may be omitted.

### First Embodiment

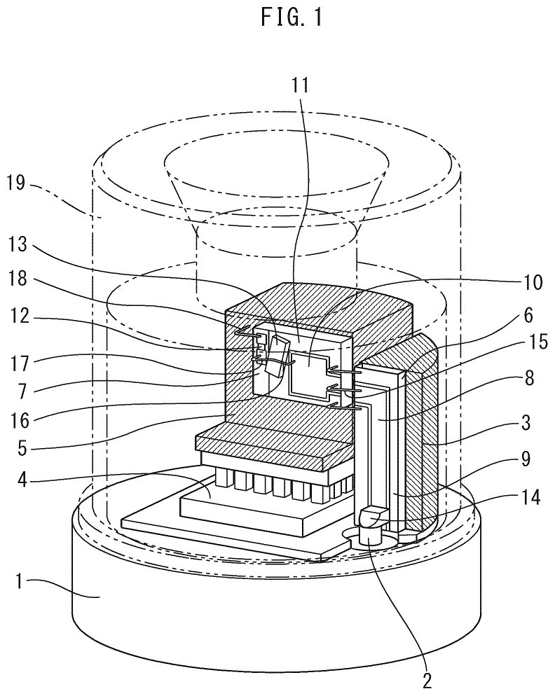

FIG. 1 is a perspective view illustrating a CAN-type optical module according to a first embodiment. A metal stem 1 has a circular plate shape. A lead pin 2 for a signal line penetrates through the metal stem 1, and is fixed to the metal stem 1 with a glass material therebetween. The metal stem 1 and the lead pin 2 are made of metal such as copper, iron, aluminum, or stainless steel, and surfaces thereof may be subjected to gold plating, nickel plating, or the like. Note that in addition to the lead pin 2 for the signal line, a plurality of lead pins such as a lead pin for supplying power to a temperature control module and a lead pin for supplying power to a laser diode portion when an EAM-LD is mounted may be provided.

A first metal block 3 and a temperature control module 4 are mounted on a top surface of the metal stem 1. The first metal block 3 is positioned in the vicinity of the lead pin 2. A second metal block 5 is mounted on the temperature control module 4. The first metal block 3 is made of metal such as copper, iron, aluminum, or stainless steel. Note that the first metal block 3 may have a structure integrated with the metal stem 1 or a structure in which an insulator such as a ceramic or a resin is coated with metal. The second metal block 5 is, for example, a block of a metal material in which a surface of a material having high thermal conductivity such as CuW is subjected to Au plating or the like. The temperature control module 4 includes a Peltier device sandwiched between a heat radiation surface and a cooling surface. The heat radiation surface is joined to the metal stem 1, and the cooling surface is mounted with the second metal block 5. First and second dielectric substrates 6 and 7 are mounted on side surfaces of the first and second metal blocks 3 and 5, respectively.

From a viewpoint of assembling performance, a metal block is separated into the first metal block 3 and the second metal block 5. Furthermore, the separation makes it possible to reduce the amount of heat which flows from outside into the second dielectric substrate 7 and the second metal block 5 through the metal stem 1. Thus, it is possible to reduce power consumption of the temperature control module 4.

A first signal line 8 and a ground conductor 9 are provided for the first dielectric substrate 6. The first signal line 8 and the ground conductor 9 are positioned with a fixed spacing therebetween to form coplanar lines. The ground conductor 9 is connected to the first metal block 3 through a via (not illustrated) formed in the first dielectric substrate 6.

A second signal line 10, a ground conductor 11, and a matching resistor 12 are provided for the second dielectric substrate 7. The second signal line 10 and the ground conductor 11 are positioned with a fixed spacing therebetween to form coplanar lines. The ground conductor 11 is also formed on a side surface of the second dielectric substrate 7.

A semiconductor optical device 13 is mounted on the second dielectric substrate 7. The semiconductor optical device 13 is, for example, a modulator integrated laser (EAM-LD) in which an electro-absorption optical modulator including an InGaAsP-based quantum well absorption layer and a distributed feedback laser diode are monolithically integrated or an MZ (Mach-Zehnder) semiconductor optical modulator. Heat generated in the semiconductor optical device 13 is diffused through the second metal block 5 and the metal stem 1.

A connection member 14 connects the lead pin 2 and one end of the first signal line 8. The connection member 14 is, for example, solder, or may be a bonding wire. A bonding wire 15 connects the other end of the first signal line 8 and one end of the second signal line 10. A bonding wire 16 connects the other end of the second signal line 10 and the semiconductor optical device 13. A bonding wire 17 connects the semiconductor optical device 13 and one end of the matching resistor 12. A bonding wire 18 connects the other end of the matching resistor 12 and the second metal block 5.

A lens-equipped cap 19 is joined to the top surface of the metal stem 1, is electrically connected to the metal stem 1, and hermetically seals the first and second metal blocks 3 and 5, the first and second dielectric substrates 6 and 7, the temperature control module 4, the first and second signal lines 8 and 10, the semiconductor optical device 13, the connection member 14, the bonding wires 15 to 18, and the like. The lens-equipped cap 19 is made of metal such as copper, iron, aluminum, or stainless steel, and has a tapered shape or a straight shape. Note that the lens-equipped cap 19 may have a structure in which an insulator such as a ceramic or a resin is coated with metal.

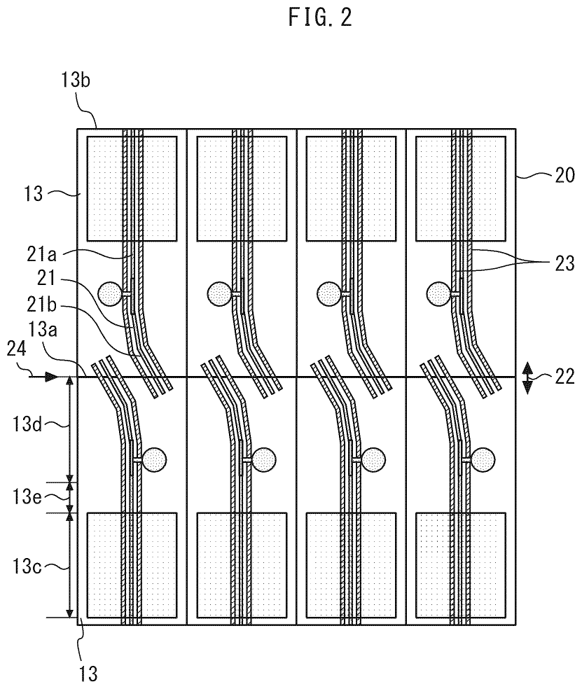

FIG. 2 is a plan view illustrating a method for manufacturing the semiconductor optical device according to the first embodiment. Two semiconductor optical devices 13 are provided for a semiconductor substrate 20 so that their respective front-end surfaces 13a face each other. Sides of the two semiconductor optical devices 13 are aligned. A plurality of pairs of the two semiconductor optical devices 13 are provided for the semiconductor substrate 20 side by side.

Each of the semiconductor optical devices includes the front-end surface 13a and a back-end surface 13b which face each other, a laser portion 13c, an optical modulation portion 13d, and an isolation portion 13e between the laser portion 13c and the optical modulation portion 13d. In the laser portion 13c, the isolation portion 13e, and the optical modulation portion 13d, a waveguide 21 is formed on the semiconductor substrate 20. The waveguide 21 includes a straight waveguide portion 21a extending in a direction perpendicular to the front-end surface 13a and an oblique waveguide portion 21b positioned closer to the front-end surface 13a than the straight waveguide portion 21a and extending obliquely with respect to the front-end surface 13a.

The oblique waveguide portion 21b of the waveguide 21 of one of the two semiconductor optical devices 13 extends to the other semiconductor optical device 13 through a border region 22 which is positioned between the two semiconductor optical devices 13. In a manner like that, the oblique waveguide portion 21b of the waveguide 21 of the other semiconductor optical device 13 extends to one of the semiconductor optical devices 13 through the border region 22.

A light emitting point recognition pattern 23 is formed on each side of the waveguide 21 of each of the semiconductor optical devices 13. The light emitting point recognition pattern 23 is a groove formed in a surface of the semiconductor substrate 20. The groove also has a current confinement or optical confinement function in some cases.

The light emitting point recognition pattern 23 extends from one of the two semiconductor optical devices 13 to the other through the border region 22 of the two semiconductor optical devices. The light emitting point recognition pattern 23 is formed symmetrical with respect to a center line of the semiconductor optical device 13 in the front-end surface 13a.

A center of the border region 22 is a cleavage position target 24. Cleavage is intended to be performed along the cleavage position target 24, but the cleavage position varies. As a result, the cleavage of the semiconductor substrate 20 occurs at some position within the border region 22 to separate the two semiconductor optical devices 13. It is necessary that the length of the border region 22 where the cleavage occurs be longer than the variation in the cleavage position, and the length is set to be approximately 20 μm, for example.

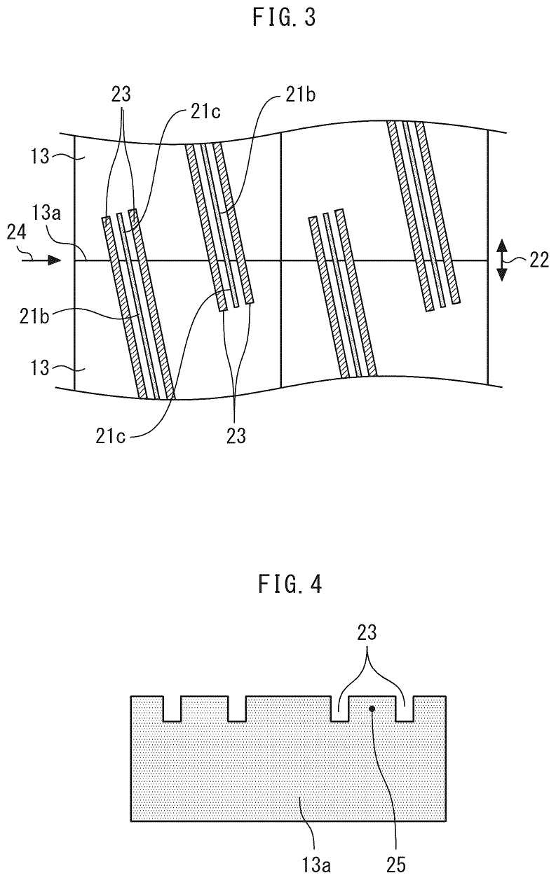

FIG. 3 is an enlarged plan view of the border region of the two semiconductor optical devices of FIG. 2. The waveguide 21 including the oblique waveguide portion 21b extending obliquely with respect to the front-end surface 13a is formed on the semiconductor substrate 20. In each of the semiconductor optical devices 13 subjected to the cleavage, the light emitting point recognition pattern 23 is formed on the semiconductor substrate 20 to reach the front-end surface 13a. In addition, the waveguide 21 extended from the other semiconductor optical device 13 is left as a dummy waveguide 21c. The dummy waveguide 21c is formed only in the vicinity of the front-end surface 13a on the semiconductor substrate 20 and is parallel to the oblique waveguide portion 21b. The light emitting point recognition pattern 23 is formed on each side of each of the waveguide 21 and the dummy waveguide 21c.

FIG. 4 illustrates the front-end surface of the semiconductor optical device according to the first embodiment. The front-end surface 13a includes four grooves of the light emitting point recognition patterns 23. A light emitting point 25 is positioned between two grooves on the right. Such a design positional relation between the light emitting point recognition pattern 23 and the light emitting point of the semiconductor optical device 13 is grasped beforehand.

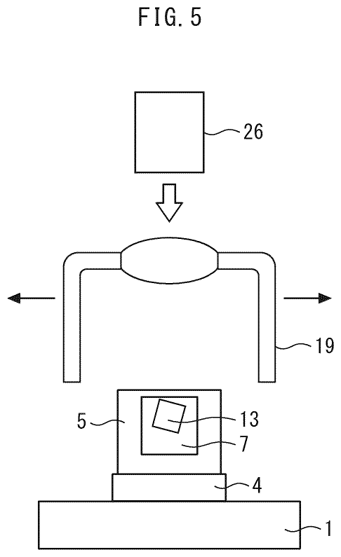

FIG. 5 illustrates a method for manufacturing the CAN-type optical module according to the first embodiment. First, the temperature control module 4 and the second metal block 5 are sequentially mounted onto the top surface of the metal stem 1. Then, an object in which the semiconductor optical device 13 manufactured by the above-described steps is mounted onto the second dielectric substrate 7 beforehand is mounted onto the side surface of the second metal block 5. Note that the semiconductor optical device 13 is mounted obliquely because an optical axis direction of light emitted from the oblique waveguide portion 21b is not perpendicular to the front-end surface 13a. Then, the design positional relation between the light emitting point recognition pattern 23 and the light emitting point of the semiconductor optical device 13 is grasped, and image recognition of the light emitting point recognition pattern 23 of the front-end surface 13a of the semiconductor optical device 13 is performed with the use of a camera 26, whereby the positions of the lens-equipped cap 19 and the light emitting point of the semiconductor optical device 13 are aligned, and the lens-equipped cap 19 is joined onto the metal stem 1.

In order to perform the image recognition of the light emitting point recognition pattern 23 through observation of the front-end surface 13a in capping, the waveguide 21 and two grooves of the light emitting point recognition pattern 23 should be within a field of view of the camera 26. Thus, the following is to be satisfied: width of field of view of camera≥mesa width of the waveguide 21+groove width×2. Furthermore, since at least three pixels are necessary for recognition of the grooves, the following is desirably satisfied: groove width×lens's magnifying power≥camera pixel size×3. Specifically, a width of the groove of the light emitting point recognition pattern 23 is preferably 2 μm to 50 μm, and a depth thereof is preferably 2 μm to 10 μm.

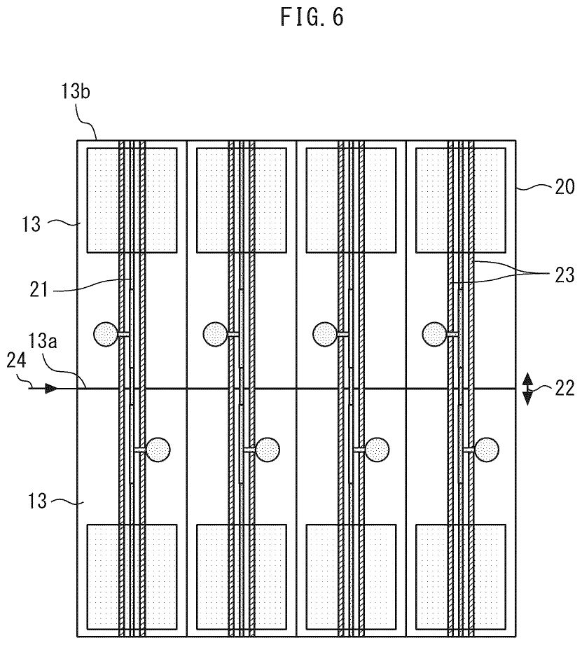

Next, the effect of the present embodiment will be described while comparing with first and second comparison examples. FIG. 6 is a plan view illustrating a method for manufacturing a semiconductor optical device according to the first comparison example. In the first comparison example, the waveguide 21 and the light emitting point recognition pattern 23 are formed perpendicular to the front-end surface 13a. Shapes of the waveguide 21 and the light emitting point recognition pattern 23 are not changed toward a longer edge of a chip in the border region 22 where cleavage occurs. Thus, even when the cleavage position varies, the positional relation between the light emitting point recognition pattern 23 and the light emitting point which is obtained from observation of the front-end surface is the same. In this case, even when the cleavage position varies, the semiconductor optical device 13 including no groove of the light emitting point recognition pattern 23 in the front-end surface 13a is not provided.

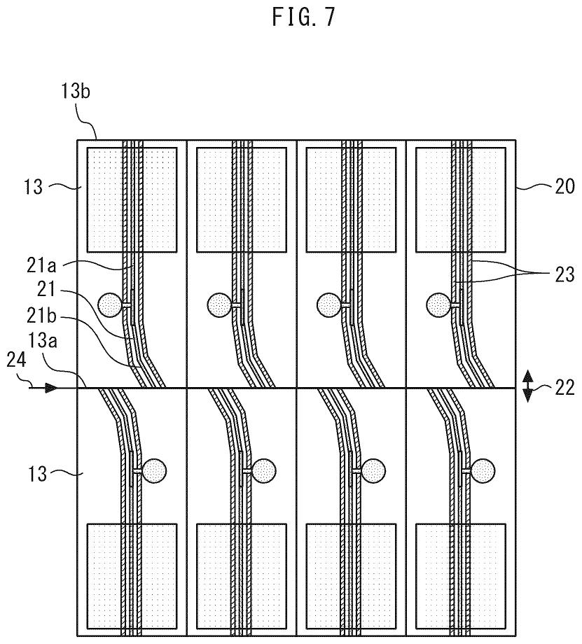

FIG. 7 is a plan view illustrating a method for manufacturing a semiconductor optical device according to the second comparison example. In the second comparison example, the waveguide 21 includes the oblique waveguide portion 21b. The waveguide 21 and the light emitting point recognition pattern 23 are formed to extend only to the cleavage position target 24 and do not enter the other semiconductor optical device 13. In this case, when the cleavage position is deviated, the semiconductor optical device 13 including no groove in the front-end surface 13a is provided; hence, the light emitting point 25 is misrecognized and production efficiency is lowered.

In response to this, in the present embodiment, the light emitting point recognition pattern 23 is formed to extend from one of the two semiconductor optical devices 13 to the other thereof through the border region 22 where cleavage is to be performed. Thus, even when the cleavage position varies in the border region 22, the cleavage occurs across the light emitting point recognition pattern 23 without fail; therefore, a semiconductor optical device including no light emitting point recognition pattern 23 in the front-end surface 13a is not provided. Hence, misrecognition of the light emitting point 25 can be prevented, and thus, production efficiency can be improved. Also, in the case where the oblique waveguide portion 21b is included, the light emitting point 25 can be recognized correctly to adjust the capping position of the lens-equipped cap 19; accordingly, variation in coupling efficiency between the CAN-type optical module and an optical fiber is reduced.

### Second Embodiment

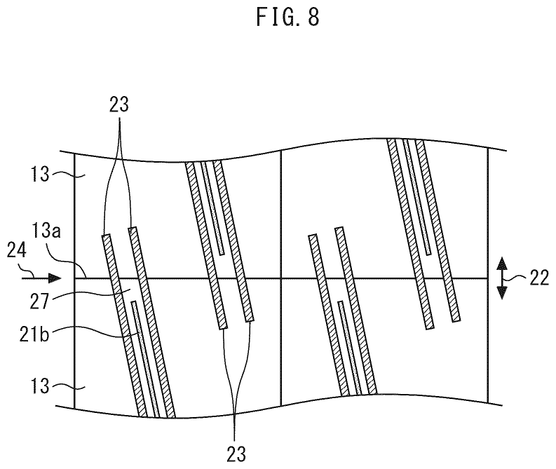

FIG. 8 is an enlarged plan view of the border region in a method for manufacturing a semiconductor optical device according to a second embodiment. In the border region 22, the waveguide 21 is not formed and a window structure 27 is formed. The waveguide 21 does not enter the other semiconductor optical device 13, but the light emitting point recognition pattern 23 on each side of the waveguide 21 enters the other semiconductor optical device 13 through the border region 22. Hence, misrecognition of the light emitting point 25 can be prevented in a manner like the first embodiment, and thus, production efficiency can be improved.

### Third Embodiment

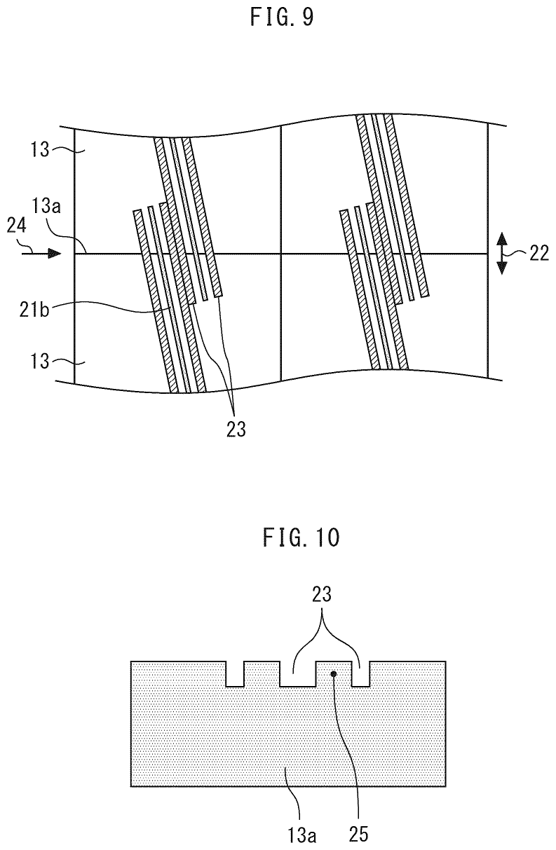

FIG. 9 is an enlarged plan view of the border region in a method for manufacturing a semiconductor optical device according to a third embodiment. FIG. 10 illustrates the front-end surface of the semiconductor optical device according to the third embodiment. The light emitting point recognition patterns 23 formed on sides of the waveguides 21 of the two semiconductor optical devices 13, which are close to centers of the semiconductor optical devices 13, are combined with each other in the border region 22. In this case, the number of grooves of the light emitting point recognition patterns 23 in the front-end surface 13a is three. In this manner, adjacent light emitting point recognition patterns 23 are combined with each other in some cases depending on an angle of inclination or a position of the waveguide 21, but an effect like that of the first embodiment can be achieved.

### Fourth Embodiment

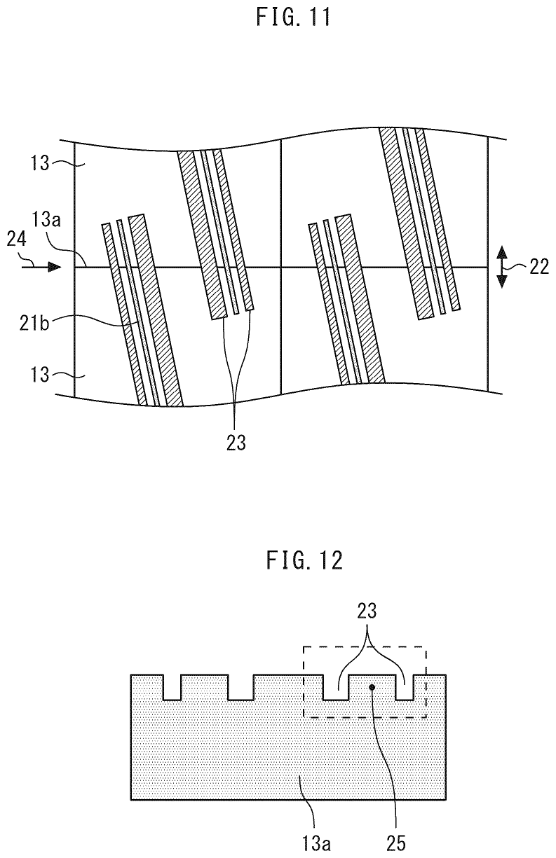

FIG. 11 is an enlarged plan view of the border region in a method for manufacturing a semiconductor optical device according to a fourth embodiment. FIG. 12 illustrates the front-end surface of the semiconductor optical device according to the fourth embodiment. A width of the light emitting point recognition pattern 23 formed on one side of the waveguide 21 of each of the semiconductor optical devices 13 is different from a width of the light emitting point recognition pattern 23 formed on the other side thereof.

An image pattern in the vicinity of the light emitting point 25 which is enclosed in a dashed line in FIG. 12 is registered beforehand. For example, in capping, a distance from a chip end portion is designated, and whether the region includes a place which matches the registered pattern is searched to recognize the light emitting point 25. In the first embodiment, the front-end surface 13a has identical patterns in two places including the two light emitting point recognition patterns 23; hence, there is a possibility that the position of the light emitting point 25 will be misrecognized depending on variation in chip width (a separation portion on a chip side). In contrast, in the present embodiment, a groove shape on the right of the waveguide 21 is different from a groove shape on the left thereof; thus, there is only one place corresponding to the image pattern registered beforehand, whereby misrecognition of the light emitting point 25 is avoided. In particular, in the case where the oblique waveguide portion 21b is included, mounting of the semiconductor optical device 13 is performed with the front-end surface 13a tilted with respect to an optical axis direction, and thus, it is difficult to focus on the front-end surface 13a, and pattern registration and image recognition cannot be performed in a wide field of view; in that case, the present embodiment is effective.

### Fifth Embodiment

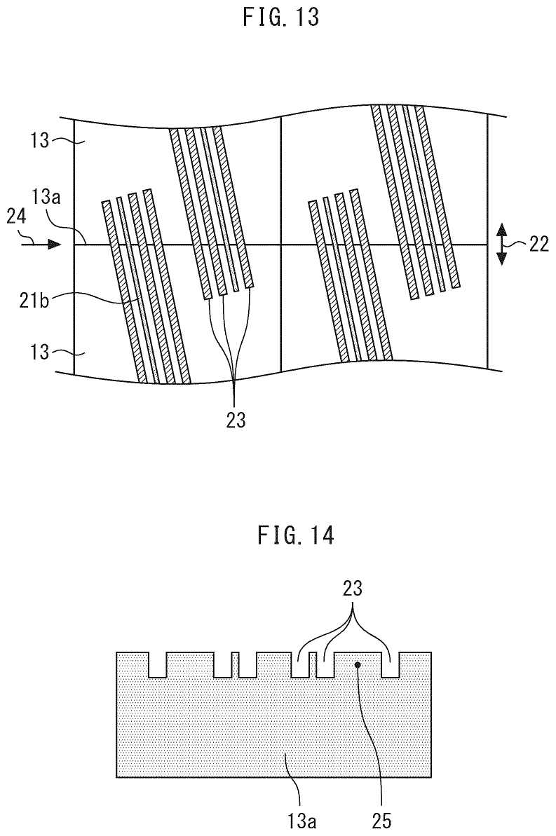

FIG. 13 is an enlarged plan view of the border region in a method for manufacturing a semiconductor optical device according to a fifth embodiment. FIG. 14 illustrates the front-end surface of the semiconductor optical device according to the fifth embodiment. The number of the light emitting point recognition patterns 23 formed on one side of the waveguide 21 of each of the semiconductor optical devices 13 is different from the number of the light emitting point recognition patterns 23 formed on the other side thereof. The groove shape on the right of the waveguide 21 is different from the groove shape on the left thereof; thus, the fifth embodiment is effective in the case where the oblique waveguide portion 21b is included, in a manner like the fourth embodiment.

### Sixth Embodiment

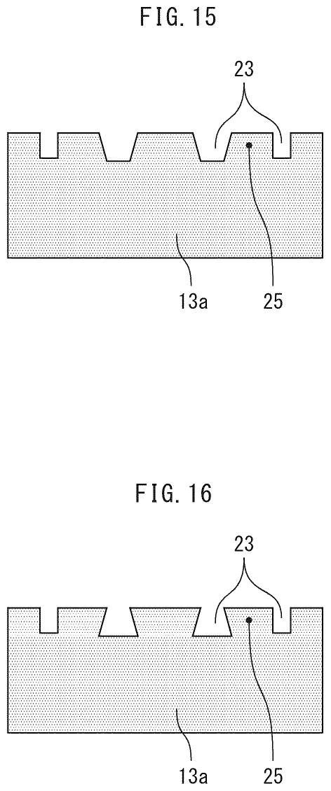

FIG. 15 illustrates the front-end surface of a semiconductor optical device according to a sixth embodiment. FIG. 16 illustrates a modification example of the front-end surface of the semiconductor optical device according to the sixth embodiment. A shape of the light emitting point recognition pattern 23 formed on one side of the waveguide 21 of each of the semiconductor optical devices 13 is different from a shape of the light emitting point recognition pattern 23 formed on the other side thereof. As groove shapes of the light emitting point recognition pattern 23, a combination of a rectangular shape and a forward mesa shape in FIG. 15 and a combination of a rectangular shape and a reverse mesa shape in FIG. 16 are given. The groove shapes of the light emitting point recognition patterns 23 are not limited to these, and a triangular or arc shape may be used. Since the groove shape on the right of the waveguide 21 is different from the groove shape on the left thereof, the sixth embodiment is effective in the case where the oblique waveguide portion 21b is included, in a manner like the fourth embodiment.

### Seventh Embodiment

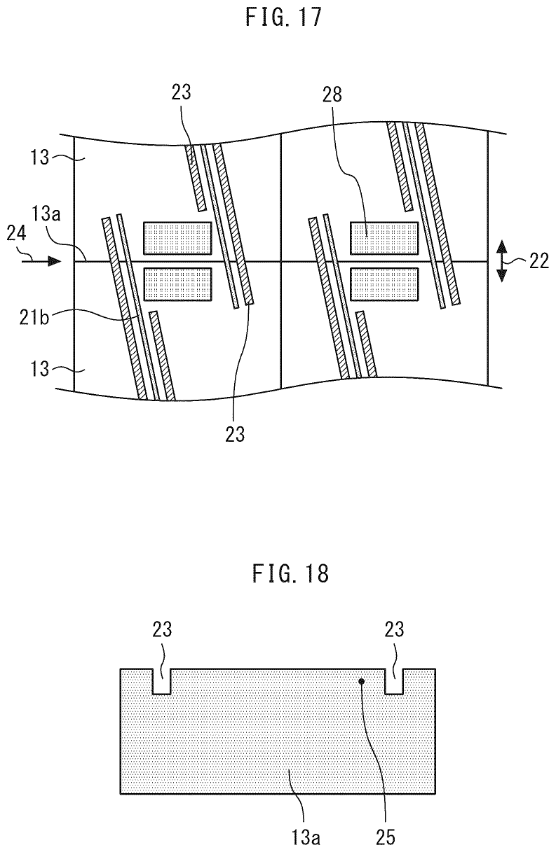

FIG. 17 is an enlarged plan view of the border region in a method for manufacturing a semiconductor optical device according to a seventh embodiment. FIG. 18 illustrates the front-end surface of the semiconductor optical device according to the seventh embodiment. The light emitting point recognition pattern 23 formed on a side of the waveguide 21 of each of the semiconductor optical devices 13, which is close to the outside of the chip, enters the other semiconductor optical device 13 through the border region 22. On a side of the waveguide 21, which is close to the inside of the chip, the light emitting point recognition pattern 23 is not formed in the border region 22 but a mounting position recognition mark 28 for the semiconductor optical device 13 is formed. The mounting position recognition mark 28 is used for position recognition at the time of mounting the semiconductor optical device 13. Note that in the case where the mounting position recognition mark 28 is provided close to the outside of the chip, the light emitting point recognition pattern 23 which is close to the outside of the chip is omitted. Even in the case where only the mounting position recognition mark 28 on one side of the waveguide 21 goes through the border region 22 in a manner described above, the front-end surface 13a includes two grooves of the mounting position recognition mark 28; thus, the light emitting point 25 can be recognized correctly.

### Eighth Embodiment

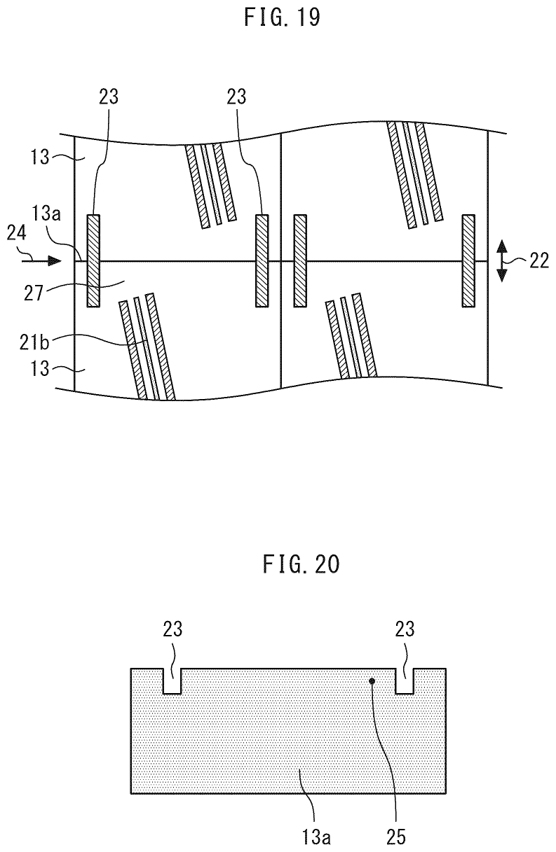

FIG. 19 is an enlarged plan view of the border region in a method for manufacturing a semiconductor optical device according to an eighth embodiment. FIG. 20 illustrates the front-end surface of the semiconductor optical device according to the eighth embodiment. In the border region 22, the waveguide 21 is not formed and the window structure 27 is formed. In the case where the window structure 27 is used, a groove in the vicinity of the waveguide 21 also affects characteristics, and therefore, the light emitting point recognition pattern 23 on each side of the waveguide 21 is not made to extend to the border region 22. In contrast, the light emitting point recognition pattern 23 formed independently of the waveguide 21 enters the other semiconductor optical device 13 through the border region 22. Therefore, misrecognition of the light emitting point 25 can be prevented in a manner like the first embodiment, and thus, production efficiency can be improved. Note that since the light emitting point recognition pattern 23 formed independently of the waveguide 21 is provided, the mounting position recognition mark 28 on each side of the waveguide 21 need not be provided.

### Ninth Embodiment

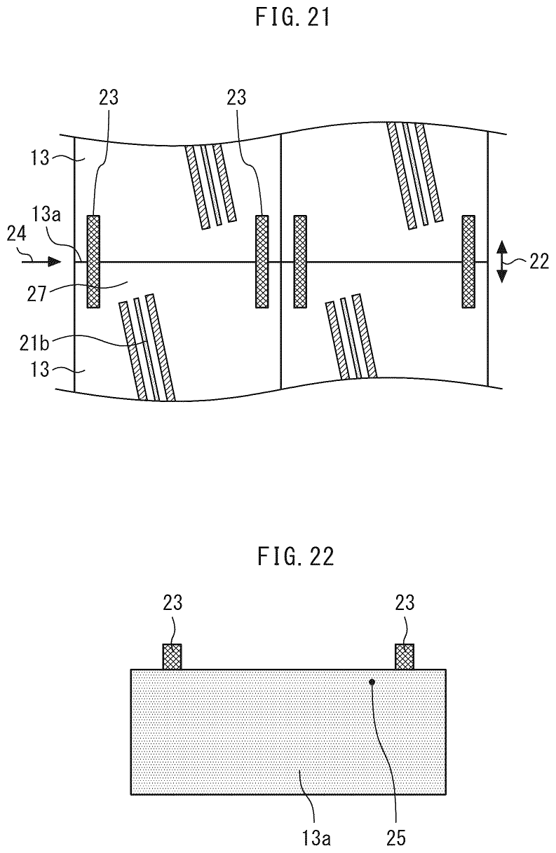

FIG. 21 is an enlarged plan view of the border region in a method for manufacturing a semiconductor optical device according to a ninth embodiment. FIG. 22 illustrates the front-end surface of the semiconductor optical device according to the ninth embodiment. The light emitting point recognition pattern 23 of the present embodiment is a protrusion. The protrusion is made of metal, plating, an insulating film, a semiconductor, or the like. The protrusion is provided for a top surface of the substrate, or may be provided for a bottom surface of the substrate on which die bonding is not performed. A width and a height of the protrusion are set so that image recognition of the light emitting point recognition pattern 23 can be performed through observation of the front-end surface 13a in capping. Since the light emitting point recognition pattern 23 is formed as a protrusion, the light emitting point 25 can be recognized even in the case where the groove cannot be provided in the front-end surface 13a. Furthermore, the protrusion can be formed by a process easier than formation of the groove.

Although the preferred embodiments and the like have been described in detail above, the present disclosure is not limited to the above-described embodiments and the like, but the above-described embodiments and the like can be subjected to various modifications and replacements without departing from the scope described in the claims. Aspects of the present disclosure will be collectively described as supplementary notes.

### (Supplementary Note 1)

A method for manufacturing a semiconductor optical device comprising:
forming two semiconductor optical devices, each of which includes a waveguide including an oblique waveguide portion extending obliquely with respect to a front-end surface, in a semiconductor substrate so that the front-end surfaces of the two semiconductor optical devices face each other;
forming a light emitting point recognition pattern, which extends from one of the two semiconductor optical devices to the other through a border region of the two semiconductor optical devices, on a surface of the semiconductor substrate; and
cleaving the semiconductor substrate within the border region to separate the two semiconductor optical devices.

### (Supplementary Note 2)

The method for manufacturing a semiconductor optical device according to Supplementary Note 1, wherein the light emitting point recognition pattern is formed on each side of the waveguide of each of the semiconductor optical devices.

### (Supplementary Note 3)

The method for manufacturing a semiconductor optical device according to Supplementary Note 2, wherein the waveguide of one of the two semiconductor optical devices extends to the other of the two semiconductor optical devices through the border region, and
the waveguide of the other of the two semiconductor optical devices extends to one of the two semiconductor optical devices through the border region.

### (Supplementary Note 4)

The method for manufacturing a semiconductor optical device according to Supplementary Note 3, wherein the light emitting point recognition patterns formed on sides of the waveguides of the two semiconductor optical devices, which are close to centers of the semiconductor optical devices, are combined with each other in the border region.

### (Supplementary Note 5)

The method for manufacturing a semiconductor optical device according to Supplementary Note 3, wherein a width of the light emitting point recognition pattern formed on one side of the waveguide of each semiconductor optical device is different from a width of the light emitting point recognition pattern formed on the other side of the waveguide of each semiconductor optical device.

### (Supplementary Note 6)

The method for manufacturing a semiconductor optical device according to Supplementary Note 3, wherein the number of the light emitting point recognition patterns formed on one side of the waveguide of each semiconductor optical device is different from the number of the light emitting point recognition patterns formed on the other side of the waveguide of each semiconductor optical device.

### (Supplementary Note 7)

The method for manufacturing a semiconductor optical device according to Supplementary Note 3, wherein a shape of the light emitting point recognition pattern formed on one side of the waveguide of each semiconductor optical device is different from a shape of the light emitting point recognition pattern formed on the other side of the waveguide of each semiconductor optical device.

### (Supplementary Note 8)

The method for manufacturing a semiconductor optical device according to Supplementary Note 3, wherein the light emitting point recognition pattern formed on one side of the waveguide of each semiconductor optical device goes through the border region, and
in the border region on the other side of the waveguide of each semiconductor optical device, the light emitting point recognition pattern is not formed but a mounting position recognition mark for the semiconductor optical device is formed.

### (Supplementary Note 9)

The method for manufacturing a semiconductor optical device according to Supplementary Note 1 or 2, wherein in the border region, the waveguide is not formed and a window structure is formed.

### (Supplementary Note 10)

The method for manufacturing a semiconductor optical device according to any one of Supplementary Notes 1 to 9, wherein the light emitting point recognition pattern is formed symmetrical with respect to a center line of the semiconductor optical device in the front-end surface.

### (Supplementary Note 11)

The method for manufacturing a semiconductor optical device according to any one of Supplementary Notes 1 to 10, wherein the light emitting point recognition pattern is a groove.

### (Supplementary Note 13)

The method for manufacturing a semiconductor optical device according to any one of Supplementary Notes 1 to 10, wherein the light emitting point recognition pattern is a protrusion.

### (Supplementary Note 13)

A method for manufacturing a CAN-type optical module comprising:
mounting a block on a top surface of a stem;
mounting the semiconductor optical device manufactured by the method according to any one of Supplementary Notes 1 to 12 onto a side surface of the block; and
grasping a design positional relation between the light emitting point recognition pattern and a light emitting point of the semiconductor optical device, aligning positions of a lens-equipped cap and the light emitting point of the semiconductor optical device by performing image recognition of the light emitting point recognition pattern of the front-end surface of the semiconductor optical device, and joining the lens-equipped cap onto the stem.

### (Supplementary Note 14)

A semiconductor optical device comprising:
a semiconductor substrate;
a waveguide formed on the semiconductor substrate and including an oblique waveguide portion extending obliquely with respect to a front-end surface; and
a light emitting point recognition pattern formed on the semiconductor substrate to reach the front-end surface.

### (Supplementary Note 15)

The semiconductor optical device according to Supplementary Note 14, further comprising a dummy waveguide formed only in a vicinity of the front-end surface on the semiconductor substrate and parallel to the oblique waveguide portion.
wherein the light emitting point recognition pattern is formed on each side of each of the waveguide and the dummy waveguide.

### REFERENCE SIGNS LIST

1 metal stem; 5 second metal block; 13 semiconductor optical device; 13a front-end surface; 19 lens-equipped cap; 20 semiconductor substrate; 21 waveguide; 21b oblique waveguide portion; 21c dummy waveguide; 22 border region; 23 light emitting point recognition pattern; 27 window structure; 28 mounting position recognition mark

Obviously many modifications and variations of the present disclosure are possible in the light of the above teachings. It is therefore to be understood that within the scope of the appended claims the invention may be practiced otherwise than as specifically described.

The entire disclosure of Japanese Patent Application No. 2025-005117, filed on Jan. 15, 2025 including specification, claims, drawings and summary, on which the convention priority of the present application is based, is incorporated herein by reference in its entirety.

1. A method for manufacturing a semiconductor optical device comprising:
forming two semiconductor optical devices, each of which includes a waveguide including an oblique waveguide portion extending obliquely with respect to a front-end surface, in a semiconductor substrate so that the front-end surfaces of the two semiconductor optical devices face each other;
forming a light emitting point recognition pattern, which extends from one of the two semiconductor optical devices to the other through a border region of the two semiconductor optical devices, on a surface of the semiconductor substrate; and
cleaving the semiconductor substrate within the border region to separate the two semiconductor optical devices.

2. The method for manufacturing a semiconductor optical device according to claim 1, wherein the light emitting point recognition pattern is formed on each side of the waveguide of each of the semiconductor optical devices.

3. The method for manufacturing a semiconductor optical device according to claim 2, wherein the waveguide of one of the two semiconductor optical devices extends to the other of the two semiconductor optical devices through the border region, and
the waveguide of the other of the two semiconductor optical devices extends to one of the two semiconductor optical devices through the border region.

4. The method for manufacturing a semiconductor optical device according to claim 3, wherein the light emitting point recognition patterns formed on sides of the waveguides of the two semiconductor optical devices, which are close to centers of the semiconductor optical devices, are combined with each other in the border region.

5. The method for manufacturing a semiconductor optical device according to claim 3, wherein a width of the light emitting point recognition pattern formed on one side of the waveguide of each semiconductor optical device is different from a width of the light emitting point recognition pattern formed on the other side of the waveguide of each semiconductor optical device.

6. The method for manufacturing a semiconductor optical device according to claim 3, wherein the number of the light emitting point recognition patterns formed on one side of the waveguide of each semiconductor optical device is different from the number of the light emitting point recognition patterns formed on the other side of the waveguide of each semiconductor optical device.

7. The method for manufacturing a semiconductor optical device according to claim 3, wherein a shape of the light emitting point recognition pattern formed on one side of the waveguide of each semiconductor optical device is different from a shape of the light emitting point recognition pattern formed on the other side of the waveguide of each semiconductor optical device.

8. The method for manufacturing a semiconductor optical device according to claim 3, wherein the light emitting point recognition pattern formed on one side of the waveguide of each semiconductor optical device goes through the border region, and
in the border region on the other side of the waveguide of each semiconductor optical device, the light emitting point recognition pattern is not formed but a mounting position recognition mark for the semiconductor optical device is formed.

9. The method for manufacturing a semiconductor optical device according to claim 1, wherein in the border region, the waveguide is not formed and a window structure is formed.

10. The method for manufacturing a semiconductor optical device according to claim 1, wherein the light emitting point recognition pattern is formed symmetrical with respect to a center line of the semiconductor optical device in the front-end surface.

11. The method for manufacturing a semiconductor optical device according to claim 1, wherein the light emitting point recognition pattern is a groove.

12. The method for manufacturing a semiconductor optical device according to claim 1, wherein the light emitting point recognition pattern is a protrusion.

13. A method for manufacturing a CAN-type optical module comprising:
mounting a block on a top surface of a stem;
mounting the semiconductor optical device manufactured by the method according to claim 1 onto a side surface of the block; and
grasping a design positional relation between the light emitting point recognition pattern and a light emitting point of the semiconductor optical device, aligning positions of a lens-equipped cap and the light emitting point of the semiconductor optical device by performing image recognition of the light emitting point recognition pattern of the front-end surface of the semiconductor optical device, and joining the lens-equipped cap onto the stem.

14. A semiconductor optical device comprising:
a semiconductor substrate;
a waveguide formed on the semiconductor substrate and including an oblique waveguide portion extending obliquely with respect to a front-end surface; and
a light emitting point recognition pattern formed on the semiconductor substrate to reach the front-end surface.

15. The semiconductor optical device according to claim 14, further comprising a dummy waveguide formed only in a vicinity of the front-end surface on the semiconductor substrate and parallel to the oblique waveguide portion.
wherein the light emitting point recognition pattern is formed on each side of each of the waveguide and the dummy waveguide.
